(19) United States
(12) Patent Application Publication
(10) Pub. No.: US 2009/0184706 A1
(43) Pub. Date: Jul. 23, 2009

(54) SENSOR DEVICE WITH ADAPTIVE FIELD COMPENSATION

(75) Inventors: Haris Duric, Helmond (NL); Josephus Arnoldus Henricus Maria Kahlman, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/302,046

(22) PCT Filed: May 11, 2007
(86) PCT No.: PCT/IB07/51786

§ 371 Date: Nov. 24, 2008

(30) Foreign Application Priority Data
May 30, 2006 (EP) 06114696.5

(51) Int. Cl. G01N 27/72; G01R 35/00

(52) U.S. Cl. 324/202; 324/228

(57) ABSTRACT

The invention relates to a magnetic sensor device comprising an excitation wire for the generation of an alternating magnetic excitation field (Bi) and a GMR sensor (12) for sensing reaction fields (B2) generated by magnetized particles (2) in reaction to the excitation fields. Moreover, it comprises a compensator (15) for the generation of a magnetic compensation field (B3) that adaptively cancels predetermined spectral components of all magnetic fields (B2, B3) which lie in the sensitive direction of the magnetic sensor element (12). Measurements of the GMR sensor (12) are thus made robust against gain variations of the sensor.

The invention relates to a magnetic sensor device comprising at least one magnetic field generator and at least one associated magnetic sensor element. Moreover, it comprises the use of such a magnetic sensor device and a method for the detection of magnetic particles in an investigation region.

From the WO 2005/010543 A1 and WO 2005/010542 A2 a magnetic sensor device is known which may for example be used in a microfluidic biosensor for the detection of biological molecules labeled with magnetic beads. The microsensor device is provided with an array of sensors comprising excitation wires for the generation of a magnetic excitation field and Giant Magneto Resistances (GMRs) for the detection of reaction fields generated by magnetized beads. The signal of the GMRs is then indicative of the number of the beads near the sensor. A problem of such magnetic sensor devices is that the GMR is subjected to the relatively strong magnetic excitation field and to other interference fields, which may lead to a corruption of the desired signal. It is therefore inter alia proposed in the WO 2005/010503 A1 to drive a wire near the GMR sensor with the sum of a sinusoidal current and an adaptive current, wherein the adaptive current just compensates reaction fields generated by beads which have been magnetized by a static external magnetic excitation field.

Based on this situation it was an object of the present invention to provide means that allow measurements with a magnetic sensor device that are robust against interferences by magnetic fields from different sources.

This object is achieved by a magnetic sensor device according to claim 1, a method according to claim 16, and a use according to claim 18. Preferred embodiments are disclosed in the dependent claims.

The magnetic sensor device according to the present invention serves for the detection of magnetized particles in an investigation region, e.g. magnetic beads in the sample chamber of a microfluidic device, and comprises the following components:
a) At least one magnetic field generator for generating an alternating magnetic excitation field in the investigation region, e.g. a sinusoidal or square wave field with a periodicity of an excitation frequency f₁. The magnetic field generator may for example be realized by a wire (“excitation wire”) on a substrate of a microchip.
b) At least one magnetic sensor element being associated with the aforementioned magnetic field generator in the sense that it can sense magnetic reaction fields generated by the magnetized particles in reaction to the aforementioned magnetic excitation field. The magnetic sensor element is typically most (or only) sensitive with respect to components of a magnetic field vector that are parallel to a “sensitive direction” of the sensor element. The magnetic sensor element can be any suitable sensor element based on the detection of the magnetic properties of particles to be measured on or near to the sensor element surface. Therefore, the magnetic sensor element is designable as a coil, magneto-resistive sensor, magneto-restrictive sensor, Hall sensor, planar Hall sensor, flux gate sensor, SQUID (Semiconductor Superconducting Quantum Interference Device), magnetic resonance sensor, or as another sensor actuated by a magnetic field.
c) At least one magnetic field compensator for generating a magnetic compensation field in the magnetic sensor element. The magnetic field compensator may for example be realized by a wire (“compensation wire”) on a substrate of a microchip.
d) A feedback controller that is coupled with its input to the magnetic sensor element and with its output to the magnetic field compensator for controlling the magnetic field compensator adaptively such that predetermined spectral components of all magnetic fields that are effective in the magnetic sensor element substantially cancel. The controller may particularly be a circuit that controls the magnitude and direction of currents flowing through compensation wires. The “predetermined spectral components” may, in the extreme case, comprise the whole spectrum of all frequencies, or they may comprise only limited bands of this whole spectrum. A magnetic field is considered as being “effective in the magnetic sensor element” in this context if can generate a signal of the magnetic sensor element; typically only the vector components of a magnetic field that lie in the sensitive direction of the magnetic sensor element constitute an “effective” part of said magnetic field. Moreover, the magnetic fields in the magnetic sensor element are considered to “cancel substantially” if the signal generated by them remains below a given threshold, for example below 2% of the maximal signal that can be generated by the magnetic sensor element, or below the magnitude of noise generated by the magnetic sensor element.

In a magnetic sensor element of the kind described above, the magnetic fields are (approximately) zero in its sensitive direction during a measurement. This has the advantage that interferences, particularly noise due to the Barkhausen effect, can be minimized, thus allowing an improved accuracy of the measurements.

According to a further development, the magnetic sensor device comprises an evaluation unit that is coupled to the magnetic sensor element or to the output of the feedback controller for determining signal components that are caused by the magnetic reaction fields of magnetized particles. Of course the magnetic sensor device can simultaneously comprise two such evaluation units, one coupled to the magnetic sensor element and one to the output of the feedback controller.

In a first important variant of the invention, the predetermined spectral components that are cancelled by the feedback controller comprise the frequencies of those signals that are caused by magnetic reaction fields of magnetized particles in the investigation region. Thus interferences are compensated just for the signals of interest. In this embodiment, the aforementioned evaluation unit would particularly be coupled to the output of the feedback controller because the direct output of the magnetic sensor element vanishes in the frequency range of interest.

In a second important variant of the invention, the predetermined spectral components that are cancelled by the feedback controller do not comprise the frequencies of those signals that are caused by magnetic reaction fields of magnetized particles in the investigation region. The feedback loop therefore does not (directly) change the magnetic signals of interest, and an evaluation unit of the kind mentioned above would typically be coupled directly to the magnetic sensor element. The removal of disturbances at other frequencies than those of interest has indirectly a positive effect on the measurements as for example sensitivity variations of the sensor element are reduced.

The magnetic sensor device may preferably comprise a demodulator between the magnetic sensor element and the feedback controller. Such a demodulator can be used to extract desired spectral components of the measurement signal if not the whole spectrum shall be processed.

The magnetic sensor element may particularly be driven with a nonzero sensing frequency f₂. Such a frequency allows to detect influences of the driving operation in the sensor signal and to position signal components one is interested in optimally with respect to noise in the signal spectrum.

In a preferred design of the magnetic sensor device, the gain of the control loop which comprises (at least) the magnetic sensor element, the feedback controller, and the magnetic field compensator is (with its absolute value) larger than 10, preferably larger than 100. As will be explained with reference to the Figures, the influence of the magnetic sensor element can be minimized in this case, thus making the measurements robust against (gain) variations of said element.

In many cases, a linear design of the feedback controller will be sufficient to achieve a satisfactory control behavior at least at a given operating point. In a further development of the invention, the feedback controller comprises a nonlinearity-module that compensates non-linear behavior of the magnetic sensor element, the magnetic field generator and/or the magnetic field compensator. Known nonlinearities can then be taken into account, thus improving accuracy of the feedback controller and extending its operating range.

In the aforementioned embodiment, the nonlinearity-module preferably comprises a characteristic curve that depends only on the geometry of the sensor device. Such a curve can for example be determined once by theoretical considerations or by calibrations for a production series of identical sensor designs.

The magnetic field compensator has to be arranged such that its desired effects in the magnetic sensor element can optimally be achieved while disturbing other components of the device as little as possible. The compensator is therefore typically disposed in the vicinity of the magnetic sensor element, e.g. not farther away from it than about 10-times the maximal diameter of the magnetic sensor element. Moreover, it is preferably disposed in a mirrored position with respect to the magnetic field generator.

The magnetic field compensator may be a hardware component of its own, e.g. a separate conductor wire. One and the same electronic hardware component may however also function as the magnetic field compensator on the one hand side and as the magnetic field generator or the magnetic sensor element on the other hand side. In this case it depends on the mode of operation of said component if a magnetic compensation field is generated, a magnetic excitation field is generated, or a magnetic field is measured. Such a dual use of hardware components is particularly possible if magnetic field compensations and magnetic measurements are made in different parts of the spectrum.

As was already mentioned, the magnetic field generator and/or the magnetic field compensator may especially comprise at least one conductor wire. The magnetic sensor element may particularly be realized by a magneto-resistive element, for example a Giant Magnetic Resistance (GMR), a TMR (Tunnel Magneto Resistance), or an AMR (Anisotropic Magneto Resistance). Moreover, the magnetic field generator, the magnetic field compensator, and the magnetic sensor element may be realized as an integrated circuit, for example using CMOS technology together with additional steps for realizing the magneto-resistive components on top of a CMOS circuitry. Said integrated circuit may optionally also comprise the control circuits of the magnetic sensor device.

In the aforementioned case, the magnetic sensor device preferably comprises signal processing circuits which are disposed in the vicinity of the magnetic sensor element, e.g. not farther away from it than about 50-times the maximal diameter of the magnetic sensor element. Such a close arrangement between magnetic sensor element and associated processing circuits has the advantage to minimize signal loss and signal disturbances on the connecting leads; it is made possible because crosstalk effects of magnetic fields generated in the processing circuits do not harm as they are compensated by the feedback controller.

The invention further relates to a method for the detection of magnetized particles in an investigation region, for example of a magnetic beads immobilized on a sensor surface, the method comprising the following steps:
a) Generating an alternating magnetic excitation field in the investigation region.
b) Generating a magnetic compensation field in a magnetic sensor element such that predetermined spectral components of all magnetic fields which are effective in said magnetic sensor element substantially cancel.
c) Determining with the help of the magnetic sensor element magnetic reaction fields generated by the magnetized particles in reaction to the magnetic excitation field.

The method comprises in general form the steps that can be executed with a magnetic sensor device of the kind described above. Therefore, reference is made to the preceding description for more information on the details, advantages and improvements of that method.

In a preferred embodiment of the method, characteristics of the system behavior are determined by calibration measurements and taken into account during the generation of the magnetic compensation field, wherein the “system” comprises all components that take part in the execution of the method (e.g. magnetic field generators, sensors, etc.). This approach is for example useful when compensating a non-linear relation between the magnetic compensation field and the amount of magnetized particles in the investigation region.

The invention further relates to the use of the magnetic sensor device described above for molecular diagnostics, biological sample analysis, or chemical sample analysis. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings in which:

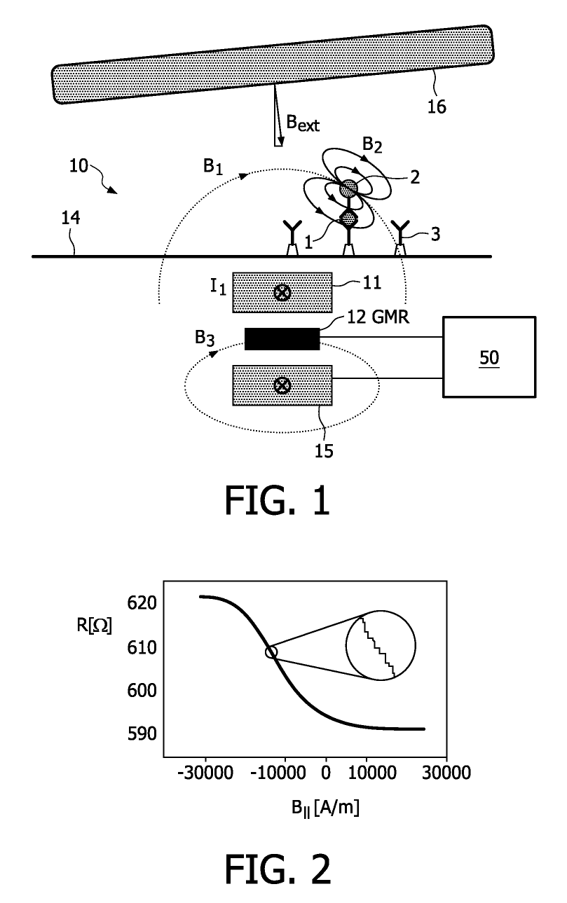

FIG. 1 shows a principal sketch of a magnetic sensor device according to the present invention;

FIG. 2 illustrates the resistance of a GMR sensor in dependence on the applied magnetic field;

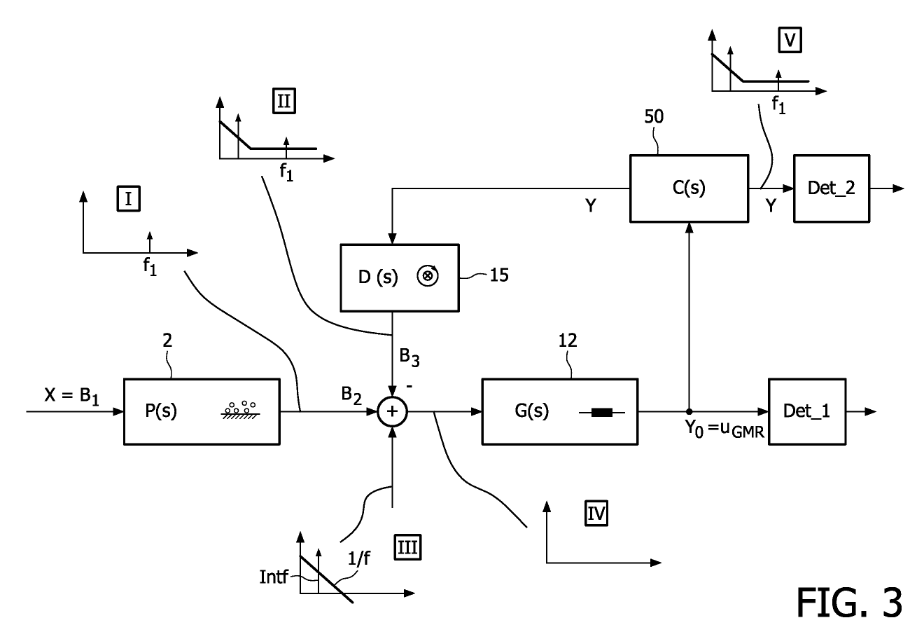

FIG. 3 shows a basic block diagram of a magnetic sensor device according to the present invention together with an illustration of the signal spectrum at different positions;

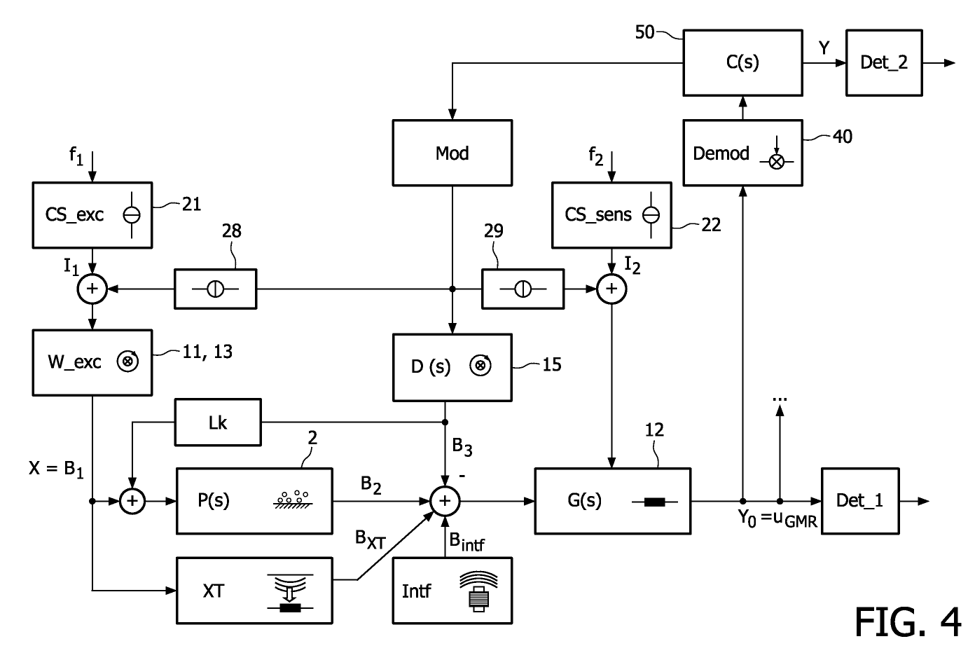

FIG. 4 shows an extended block diagram of magnetic sensor devices according to the present invention;

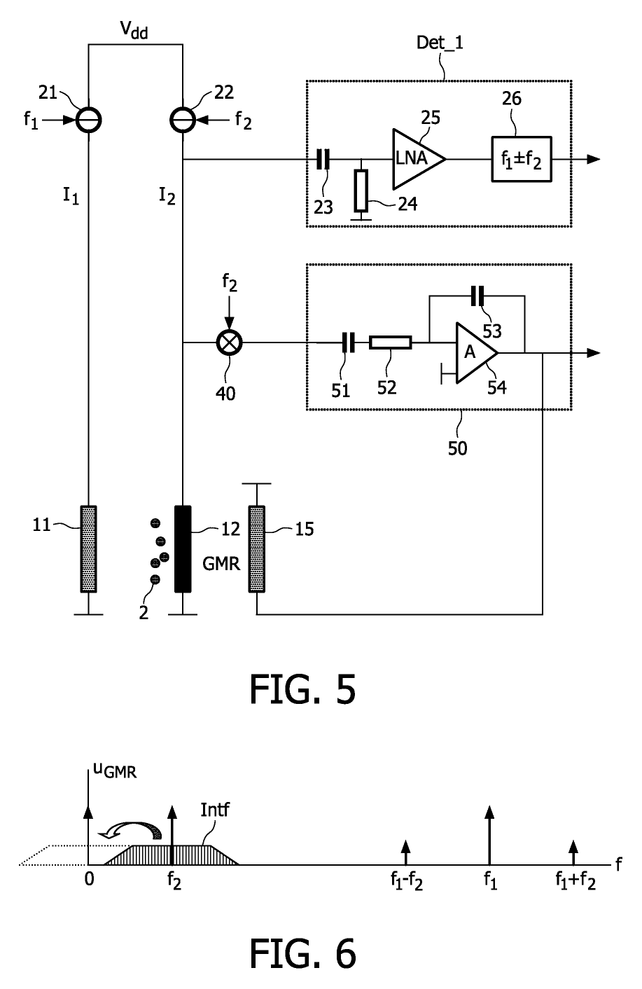

FIG. 5 shows the circuit of a magnetic sensor device according to the present invention with the compensation of low-frequency magnetic fields;

FIG. 6 shows the signal spectrum for the magnetic sensor device of FIG. 5;

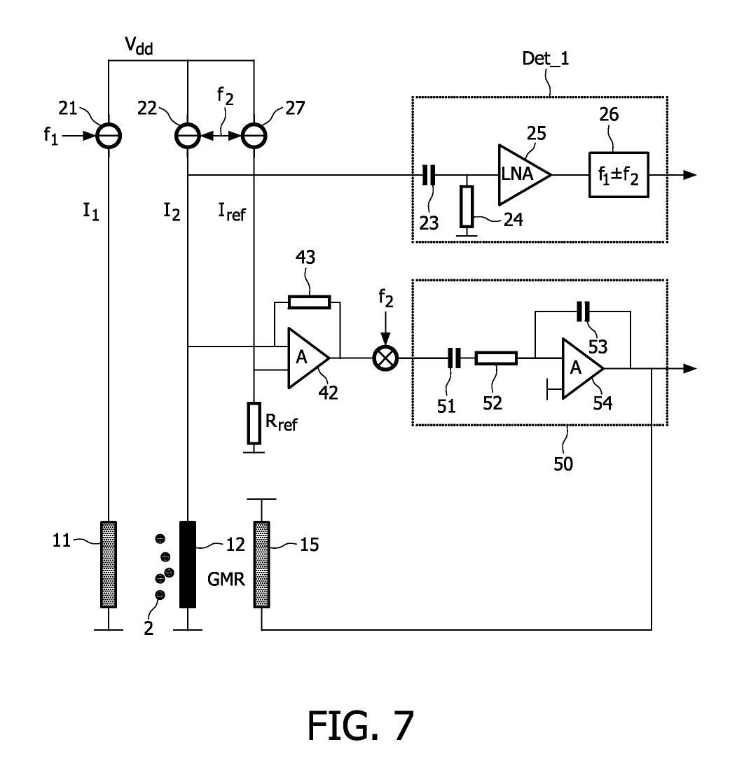

FIG. 7 shows a variant of the magnetic sensor device of FIG. 5 which comprises a common mode circuit prior to the feedback controller;

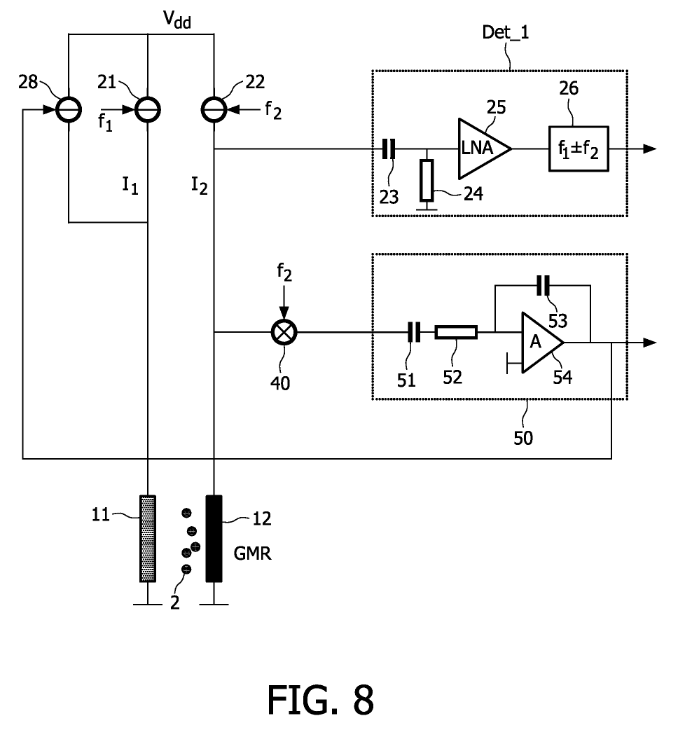

FIG. 8 shows a magnetic sensor device according to the present invention that uses the excitation wires also as magnetic field compensator;

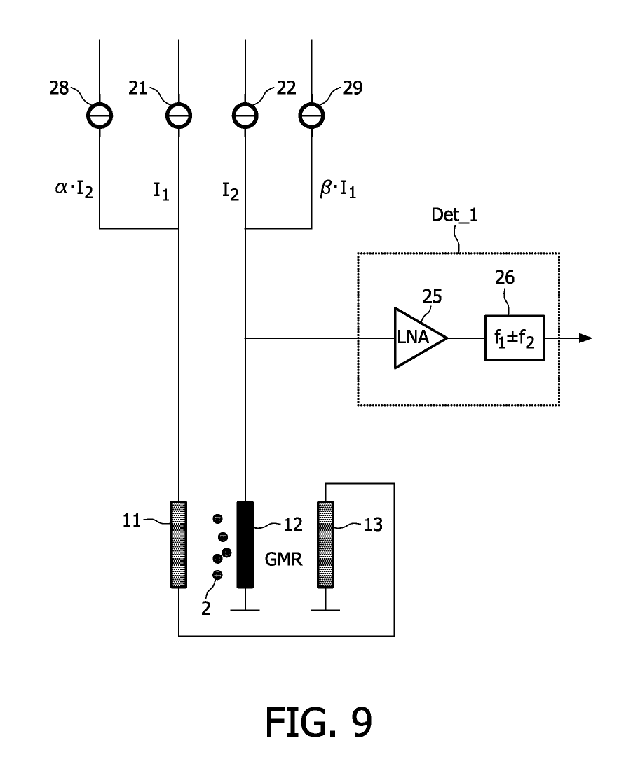

FIG. 9 shows a magnetic sensor device according to the present invention that applies adaptive current sources for driving the excitation wires and the magnetic sensor element, respectively;

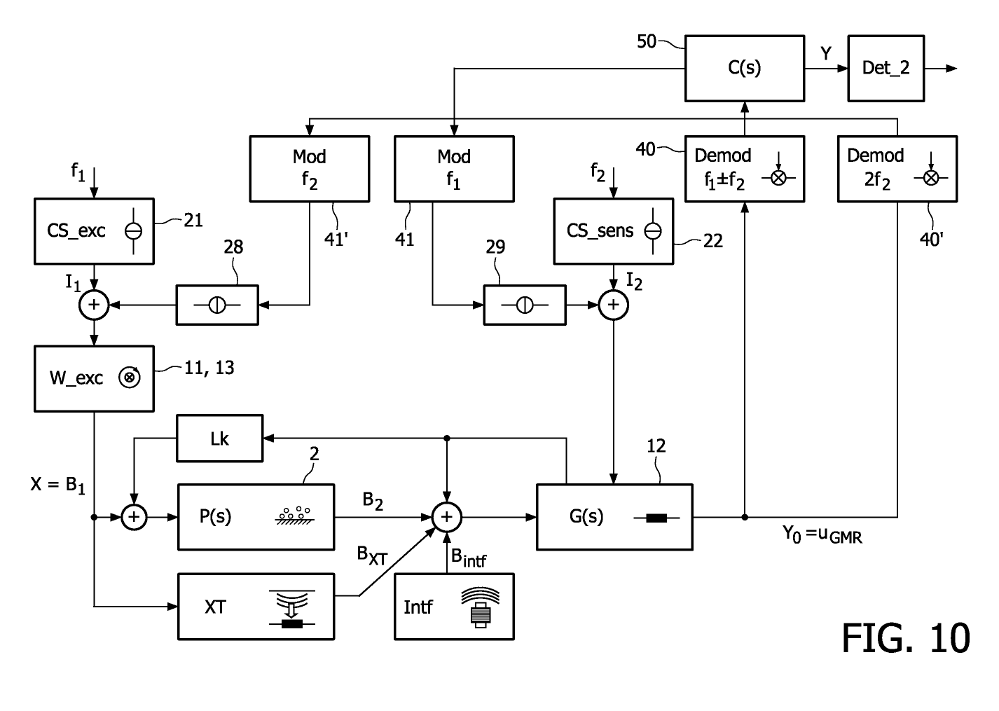

FIG. 10 shows the block diagram of the device of FIG. 9.

Like reference numbers in the Figures refer to identical or similar components.

Magneto-resistive biochips have promising properties for bio-molecular diagnostics, in terms of sensitivity, specificity, integration, ease of use, and costs. Examples of such biochips are for example described in WO 2003/054566, WO 2003/054523, WO 2005/010542 A2, WO 2005/010543 A1 or Rife et al. (Sens. Act. A vol. 107, p. 209 (2003)), which are incorporated into the present application by reference.

FIG. 1 illustrates the principle of a single sensor 10 for the detection of superparamagnetic particles or beads 2. A magnetic (bio)sensor device consisting of an array of (e.g. 100) such sensors 10 may be used to simultaneously measure the concentration of a large number of different biological target molecules 1 (e.g. protein, DNA, amino acids) in a solution (e.g. blood or saliva). In one possible example of a binding scheme, the so-called “sandwich assay”, this is achieved by providing a binding surface 14 with first antibodies 3, to which the target molecules 1 may bind. Superparamagnetic beads 2 carrying second antibodies may then attach to the bound target molecules 1. An excitation current I1 flowing in the excitation wire 11 of the sensor 10 generates a magnetic excitation field B1, which magnetizes the superparamagnetic beads 2. The stray field B2 from the superparamagnetic beads 2 introduces an in-plane magnetization component in the Giant Magneto Resistance GMR 12 of the sensor 10, which results in a measurable resistance change.

FIG. 1 further illustrates as an exemplary source of magnetic interference with the GMR sensor 12 an actuation coil 16 placed in the cartridge (or the reader) of the sensor device to generate large magnetic fields Bₑₓₜ that can attract (or repel) the magnetic particles 2 towards (or away from) the binding surface 14. A (random) misalignment of the sensor chip and the actuation coil 16 or non-uniform actuation fields Bₑₓₜ will then cause a significant in-plane interference component of the magnetic field Bₑₓₜ inside the GMR sensor 12.

In magnetic sensor devices of the kind described above, the basic sensor elements (e.g. AMR or GMR) often have a size that encloses more than one magnetic domain and are therefore prone to Barkhausen noise. The Barkhausen effect is a series of sudden changes in the size and orientation of ferromagnetic domains, or microscopic clusters of aligned atomic magnets, that occurs during the magnetization or demagnetization of ferromagnetic materials. As known, (Barkhausen) noise associated with a magnetic structure is directly proportional to the strength of any time-varying magnetic field applied to it.

FIG. 2 depicts the resistance R of a GMR element 12 (or a similar magneto-resistive element) as a function of the magnetic field component B_{∥} parallel to the sensitive direction of the GMR element (i.e. the sensitive layer of the GMR stack). The slope of the curve corresponds to the sensitivity s_{GMR} of the magnetic sensor element and depends on B_{∥}. Unfortunately the sensitivity s_{GMR} and therefore the effective gain of a measurement with the GMR element is sensitive to non-controllable parameters, for example stochastic sensitivity variations due to magnetic instabilities in the sensor, externally applied magnetic fields, production tolerances, mechanical stress, aging effects, temperature, or memory effects from e.g. magnetic actuation fields.

FIG. 2 further illustrates in this respect with an inset the effect of Barkhausen noise on the resistance value R. Apparently the smooth magnetization curve is revealed as a series of discrete jumps when observed on a smaller scale. These sudden, discontinuous domain wall movements can be studied in the time- and in the frequency domain, and may be interpreted as sensitivity noise (or gain noise) of the sensor. The effects of said domain wall movements on the sensor signal are twofold:
The sensitivity s_{GMR} of the sensor shifts, which affects the calibration point.
A broadband noise spectrum is generated, which degrades the signal-to-noise ratio.

The problem is now that any magnetic interference originating from e.g. actuation coils 16, mains, PC-monitors, permanent magnets, etc. can cause a shift in the sensor sensitivity s_{GMR} and generate a broadband (Barkhausen) noise spectrum. Since this interference can severely degrade the measurement accuracy and one cannot rely on the probability of the absence of interference, protective measures are highly desirable.

As a solution it is proposed here to include the sensor 12 in a control loop together with at least one “magnetic field compensator” which will adaptively force in-plane magnetic fields in the sensitive layer to zero. The sensor 12 will thus be dynamically shielded from any interference.

In FIG. 1, the aforementioned field compensator is realized by an additional conductor wire 15 disposed symmetrically to the excitation wire 11 below the GMR sensor 12. The field compensator generates a magnetic “compensation field” B₃ in the sensor 12 when a current is applied to it by a feedback controller 50 (which will be explained in more detail below). The shown symmetric geometry has the advantage that the magnetic crosstalk from the excitation wire 11 can be cancelled if the compensator 15 conducts in a static situation a current substantially equal to the excitation current I₁, with as result that the in-plane magnetic field due to the excitation current is cancelled at the location of the GMR sensor 12. In order to create better homogeneous fields between the excitation and compensation wires 11 and 15, these wires can optionally be made wider in the horizontal direction of FIG. 1.

In a static situation an additional current can further be forced by the feedback controller 50 through the field compensator 15, which will compensate for the magnetic field caused by the internal magnetic crosstalk of the sensing current which drives the GMR sensor 12.

After the magnetic particles 2 are introduced on top of the binding surface 14, the excitation field B₁ magnetizes them (together with the compensations field B₃). The resulting reaction field B₂ coming from said particles 2 can then be compensated for at the location of the GMR sensor 12 by a feedback current in the compensator 15, which is a measure for the amount of the magnetic particles.

An advantage of the shown “vertical” arrangement is that the magnetic particles 2 are very close to the excitation wire 11 and will therefore experience a strong excitation field B₁. Moreover, the complete geometry is relatively small in the horizontal direction, thus allowing a better surface-area utilization. Finally, the dynamic range of the required feedback loop can be kept small because a large part of the magnetic fields are already suppressed by the geometry.

The required feedback control of a field compensator 15 will now be explained in more detail with reference to the general system diagram of FIG. 3. For the sake of clarity, a situation is considered where a DC sensing current I₂ is applied to the GMR sensor 12.

According to FIG. 3, the excitation field B₁ is provided as an input X to “the process”, i.e. the binding and magnetization kinetics of the particles 2. Said process generates with its transfer function P(s) the reaction field B₂ as output. The reaction field B₂ is superposed with the magnetic compensation field B₃ generated by the compensator 15 (transfer function D(s)) and with magnetic interference fields, which originate from e.g. external coils and further comprise the intrinsic 1/f noise of the GMR sensor. The sum of all mentioned fields is sensed by the GMR sensor 12 (transfer function G(s)), which generates as output the measurement signal Y₀ (typically the voltage u_{GMR} across the GMR sensor).

The GMR signal Y₀ can be processed (as usual) by a first evaluation unit Det_1 to determine the signal components of interest (i.e. the one which is generated by the reaction fields B₂). In the feedback approach proposed here, the sensor signal Y₀ is fed to a feedback controller 50 with transfer function C(s). The output Y of this controller drives the compensator 15 to generate the compensation field B₃, which closes the loop. The output Y of the controller 50 can further be provided to a second evaluation unit Det_2 to determine the signal component of interest.

FIG. 3 further shows the power spectral density (PSD) diagrams I-V at several positions of the system. The PSD I shows the reaction field B₂ originating from the excited magnetic particles 2 at frequency f₁. At the same time a (low frequency) interfering magnetic field acts on the sensor, which is indicated by the line “Intf” in the PSD III. The 1/f noise, originating from intrinsic domain rotations in the free layer of the GMR sensor 12, is also indicated in PSD III.

In a steady-state situation, the feedback loop provides a PSD II that compensates for the magnetic fields at the input of the sensor 12, which results in a close to zero signal indicated by PSD IV. For the sake of simplicity, the thermal noise is neglected here. Finally, PSD V is obtained at the output of the feedback controller 50 and is proportional to the effort that is needed to compensate the magnetic fields at the input of the sensor 12.

In order to suppress the quantization-like effects of the domain-wall movements (Barkhausen), dither may additionally be injected into the control loop to linearize the sensor response, which is a well-known technique in Analog-to-Digital Converters. Obviously, this effect may also be achieved by residual (f₁ or f₂) field components.

By forcing the magnetic field inside the GMR sensor 12 to zero, the sensor (Barkhausen) noise is drastically reduced. If the magnetic field cancellation is well maintained for all frequencies and at each position in the sensor, this technique can lead to superior measurement accuracy. Furthermore the generation of new domain walls is prevented due to the absence of large magnetic fields.

The reduction of the magnetic field at the input of the sensor 12 is determined by the loop gain, which can be calculated as C(s)·G(s)·D(s). The system transfer H(s) can be made independent of the (unstable) sensor gain G(s) by choosing the controller gain C(s) such that the loop gain C(s)·G(s)·D(s)>>1:

$$H ( s ) = \frac{Y ( s )}{X ( s )} = \frac{C ( s ) \cdot G ( s ) \cdot P ( s )}{1 + C ( s ) \cdot G ( s ) \cdot D ( s )} \approx \frac{P ( s )}{D ( s )}$$

The system transfer H(s) is thus determined only by the process P(s) and the compensator transfer D(s). D(s) is highly stable and depends only on the physical position and magnetic coupling between the sensor and the compensator, which is mechanically fixed for the lifetime of each sensor device. It is important to notice that the compensator transfer D(s) should be made independent of the temperature. If the compensation wire is for example driven by a voltage source, the current (and thus the magnetic field strength) will be dependent on the temperature of the wire (typically with a factor of (1+α·(T−T₀))⁻¹). However, the effect of self-heating and alike can be avoided by driving the compensation wire with a current source. Current sources that are temperature independent (or proportional to the absolute temperature) are commonly realized in monolithically integrated circuits.

The aforementioned H(s)-independency of the sensor gain G(s) allows for a static auto-calibration procedure, wherein a calibration point can be (repeatedly) established as follows: Prior to the actual biological measurement the system transfer is measured and used as a zero value. Since the magnitude of the magnetic excitation field X(s)=B₁ is fixed, any change in the process transfer P(s) due to the magnetic particles will cause a change in the output signal Y(s), which is exactly what is to be measured.

A further advantage of the system of FIG. 3 is that the effects of the temperature and IC-process spread on the sensor preamplifier and the loop-filter electronics are also removed from the system transfer. Moreover, the sensor 12 is to a large extent linearized by the feedback loop. Finally, the approach enables the use of a sensor on-top-of signal processing means (e.g. back-end of the CMOS process), as interfering magnetic fields originating from said processing means can be suppressed.

FIG. 4 shows an extended version of the system diagram of FIG. 3 which comprises several particular embodiments of the present invention.

As a first extension, FIG. 4 comprises the excitation current source CS_exc that generates an excitation current I₁ of frequency f₁. Said current I₁ drives the excitation wires W_exc which generate the excitation field B₁. Similarly, the diagram includes the sensing current source CS_sens that generates a sensing current I₂ of frequency f₂ for driving the GMR sensor 12. Other sources of interference fields are summarized by a block “Intf”.

As a particular source of interference, the magnetic crosstalk XT has been introduced, i.e. the magnetic field components B_{XT} of the excitation field B₁ that directly affect (with frequency f₁) the GMR sensor 12.

On the side of the controller, a demodulator Demod and a modulator Mod have been inserted as optional components before and after the controller 50, respectively. Moreover, optional current sources 28 and 29 have been added. They are controlled by the controller 50 and add current to the excitation current I₁ and the sensing current I₂, respectively. The function of all aforementioned components will be discussed below in connection with preferred embodiments.

Finally, a leakage branch Lk has been added between the compensation field B₃ and the input of the process P(s). In real situations, the magnetic particles 2 are not isolated from the compensation field B₃, so that there is some feedback magnetic field “leaking” through the magnetic particles 2 into the sensor 12. It can however been shown that this effect usually has a negligible influence on the total signal (the strength of magnetic fields drops with distance; both the GMR sensor and the beads will therefore experience a declined compensation field; the correspondingly reduced magnetization of the beads generates a reaction field that drops once again on its way to the sensor. The effect of distance drop therefore roughly squares in the reaction fields).

Due to the leakage, the transfer function of the compensation wire, D(s), may become non-linear for large concentrations of magnetic particles. This introduces an error in the measurements, in particular a ‘systematic error’ that can be compensated for. By doing a certain number of experiments, the shape of the non-linear relation between D(s) and the amount of magnetized particles can be predetermined and stored in some system memory. This curve will be the same for all sensors that have the same geometry (within certain production tolerances). Since the influence of this effect is a-priori known, e.g. a micro-controller can be used to compensate for it.

In a first particular embodiment of the invention, the sensor 12 is driven with a DC current (i.e. f₂=0), and the complete magnetic field spectrum up to the excitation frequency f₁ is compensated (“broadband cancellation”). FIG. 4 represents this case if the blocks Det_1, Demod, and Mod as well as the current sources 28 and 29 are omitted. A (plurality of) compensation actuator(s) 15 is positioned near the GMR sensor 12 in such a way that the coupling of the magnetic field B₃ from said actuator(s) into the GMR sensor is maximized and that the magnetic field originating from any interference (bead actuation, excitation current, sensing current, mains, etc.) is optimally cancelled at each position on the sensor. The placement of the feedback actuator(s) 15 can be adjacent to the sensor side, top or bottom (cf. FIG. 1). Measures should be taken to distinguish between the capacitive and inductive cross-talk, magnetic cross-talk at f₁, and the desired signal from the magnetic beads at f₁. As the sensor is sensed by a DC current in this embodiment, all voltage components (capacitive and inductive cross-talk, magnetic cross-talk and magnetic bead signal) fall on the same frequency, f₁, and are difficult to differentiate. Therefore, it is desirable to reduce the cross-talk components. The magnetic cross-talk can be reduced by e.g. aligning the centerline of the excitation current wire and the free layer of the GMR sensor. An electric (i.e. capacitive and inductive) cross-talk reduction can be achieved by e.g. phase-sensitive (orthogonal) detection, as the electric cross-talk signal is phase-shifted with respect to the magnetic (bead and cross-talk) signal.

If for example a 100-fold reduction at the excitation frequency f₁=100 kHz is required, then a closed-loop bandwidth of at least 10 MHz is needed, hence

$$H ( s ) = \frac{1}{1 + \frac{s}{2 π \cdot {10}^{7}}} .$$

Additionally, a DC-block can be added in the controller C(s) to remove DC voltage originating from the sensing current I₂.

In a second particular embodiment of the invention, the demodulator Demod and the modulator Mod from FIG. 4 are present while the components Det_1, 28 and 29 are still omitted. The sensing current I₂ may be AC or DC. By the demodulation-modulation steps the loop is closed selectively only at desired frequencies, e.g. the excitation frequency f₁ if the demodulator Demod is driven at f₁−f₂ or f₁+f₂ and the modulator Mod is driven at f₁ (this approach only reduces the effect of sensor gain variations for the bead measurement at frequency f₁±f₂).

Compared to the first embodiment, the required closed-loop bandwidth to reduce amplitude variations at f₁ may be significantly lower, namely e.g. 1 kHz instead of 10 MHz. It should be noted that the f₁ modulator Mod must be able to cope with a large dynamic range and high accuracy (0.1 per mil).

FIG. 5 shows the circuit of a magnetic sensor device with a low-frequency (LF) dynamic shielding, an AC sensing current I₂, and a high-frequency read-out. In this a highly preferred embodiment a low-bandwidth controller 50 suppresses LF magnetic fields. Due to the multiplication of the magnetic field and the sensing current I₂, the frequency of the interfering magnetic field Intf is shifted in the device by the sensing current frequency f₂ as indicated in FIG. 6. To correct for this effect and to shift the spectrum back (arrow in FIG. 6), a demodulator 40 is added between the controller 50 and the GMR sensor 12 and driven with frequency f₂. Such a demodulator can for example be low-cost implemented as a quad of CMOS chopper switches.

The demodulated signal is fed in the controller 50 via a capacitor 51 and a resistor 52 to the inverting input of an operational amplifier 54. Said input is coupled via a second capacitor 53 to the output of the amplifier, and the non-inverting input of the amplifier 54 is coupled to ground. The output of the amplifier 54 drives the compensator 15.

The measurement signal of the GMR sensor 12 is further sent in an evaluation unit Det_1 via a high-pass filter (capacitor 23, resistor 24) and a low-noise amplifier 25 to a demodulator 26 of frequency f₁±f₂, where the signal of interest is extracted. The excitation wire 11 and the GMR sensor 12 are driven by current sources 21, 22 with frequencies f₁ and f₂, respectively.

If the output of the control loop (i.e. of the amplifier 54) is used to determine the bead signal by an evaluation unit Det_2 (not shown in FIG. 5) and if the whole (magnetic) frequency spectrum is compensated at the sensor location, it is important that the relation between the output signal (current or voltage) and the magnetic compensation field is fixed (i.e. temperature independent). This can be achieved by driving the compensation wire 15 with a current source, e.g. by inserting a voltage-to-current converter between the amplifier 54 and the compensation wire 15, or by using an Operational Transconductance Amplifier (OTA) as amplifier 54. The compensation current can be mirrored, scaled down and used as the output signal.

The described approach has the strong advantage that the frequencies can be chosen such that the detection signal f₁±f₂ is beyond the control bandwidth, so that the leakage has no influence. As a result the typical sensor geometry using planar excitation wires may be used. Additionally, a DC blocking means (a zero in the loop filter 50, or an f₂ notch filter or bridge structure prior to demodulation) may be added to remove DC originating from f₂.

If for example f₁=2 MHz, f₂=100 kHz, and the closed loop bandwidth BW=10 kHz, then the feedback loop will reduce magnetic fields from 0.1 Hz up to 10 kHz, which is sufficient to reduce actuation fields and power supply interference (50/60 Hz).

FIG. 7 shows a variation of the previous embodiment, wherein the sensing current I₂ is made a part of the common-mode circuit and wherein applying differential signaling mode reduces the influence of the sensing current at frequency f₂. To avoid the influence of large f₂ sensing current components, the non-inverting terminal of an operational amplifier 42 can be connected to a resistance R_{ref} and an adjustable current source 27 generating the reference current I_{ref} of frequency f₂, which can be scaled such that in a static situation the voltage at the non-inverting terminal is substantially equal to the voltage across the GMR sensor. In this way the sensing current is made common-mode and the loop will compensate only for the differential-mode magnetic interference at f₂. The resistance R_{ref} may optionally be another GMR strip that is made insensitive to beads (by e.g. a cover layer). In this way also the temperature drift can be made a part of the common-mode signal.

Obviously, by applying a DC sensing current (f₂=0 Hz), the demodulator 40 and a DC-block in the LF feedback loop of FIG. 7 are made obsolete. In this regime, also the non-time-varying magnetic fields can be suppressed.

FIG. 8 shows a further variant of the circuit of FIG. 5 wherein the controller 50 drives an additional current source 28 coupled to the excitation wire 11. The excitation wire 11 is therefore also used as a compensator. This is possible because the detection signal f₁±f₂ is beyond the control bandwidth, so that the leakage principally has no influence.

In the embodiment shown in FIG. 9, a sensor geometry with two excitation wires 11 and 13 at both sides of the GMR sensor 12 is used to cancel the magnetic fields from the excitation current I₁ (frequency f₁) and the sensing current I₂ (frequency f₂). An adjustable current source 28 adds current α·I₂ at frequency f₂, which is applied to the excitation wires 11, 13 to compensate for the self-magnetization field generated by the sensing current I₂. At the same time a second adjustable current source 29 supplies a current β·I₁ at frequency f₁ to the GMR sensor 12 to generate a self-magnetization field in the GMR, compensating for the magnetic field originating from the excitation and from the beads.

FIG. 10 shows the block diagram for the control loop of the aforementioned embodiment in more detail based on the block diagram of FIG. 4. In a first path, the sensor signal Y₀ is demodulated with frequency f₁−f₂ (or f₁+f₂) by a demodulator 40, sent through the controller 50, modulated by a modulator 41 with frequency f₁, and used to steer the adjustable current source 29 providing an additional sensing current to the GMR sensor 12. In a second path, the sensor signal Y₀ is demodulated with frequency 2f₂ by a demodulator 40′, modulated by a modulator 41′ with frequency f₂, and used to steer the adjustable current source 28 providing an additional excitation current to the excitation wires 11, 13.

The described embodiments can be varied in many ways. In particular, more complex compensation field generating means can be applied to provide appropriate field cancellation at each sensor position (e.g. several actuator segments in a CMOS top-metal layer).

In summary, the invention solves the problem that any magnetic interference originating from e.g. actuation coils, magnetic bead excitation- and stray field (at f₁), self-magnetization field from the sense current (at f₂), mains, PC-monitors, permanent magnets, CMOS biasing circuits, etc. can cause a shift in the sensor calibration point and generate a broadband (Barkhausen) noise spectrum by including the magnetic sensor element in a control loop together with a (plurality of) field-cancellation actuator(s). Said actuators adaptively force the in-plane magnetic field in the sensitive layer of the sensor element to zero, thus shielding the sensor dynamically from the interference.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device (10) for detecting magnetized particles (2) in an investigation region, comprising
a) a magnetic field generator (11, 13) for generating an alternating magnetic excitation field (B1) in the investigation region;
b) an associated magnetic sensor element (12) for sensing magnetic reaction fields (B2) generated by the magnetized particles (2) in reaction to the magnetic excitation field (B1);
c) a magnetic field compensator (15) for generating a magnetic compensation field (B3) in the magnetic sensor element (12);
d) a feedback controller (50) that is coupled to the magnetic sensor element (12) and to the magnetic field compensator (15) for controlling the magnetic field compensator (15) adaptively such that predetermined spectral components of all magnetic fields (B2, B3, BXT, Bintf) which are effective in the magnetic sensor element (12) substantially cancel.

2. The magnetic sensor device (10) according to claim 1,
characterized in that an evaluation unit (Det_2, Det_1) coupled to the magnetic sensor element (12) or to the output of the feedback controller (50) for determining signal components that are caused by magnetic reaction fields (B2) is comprised.

3. The magnetic sensor device (10) according to claim 1,
characterized in that said predetermined spectral components comprise the frequencies (f1±f2) of signals caused by magnetic reaction fields (B2).

4. The magnetic sensor device (10) according to claim 1,
characterized in that said predetermined spectral components do not comprise the frequencies (f1±f2) of signals caused by magnetic reaction fields (B2).

5. The magnetic sensor device (10) according to claim 1,
characterized in that the magnetic sensor device (10) comprises a demodulator (40) between the magnetic sensor element (12) and the feedback controller (50).

6. The magnetic sensor device (10) according to claim 1,
characterized in that the magnetic sensor element (12) is driven with a sensing frequency f2.

7. The magnetic sensor device (10) according to claim 1,
characterized in that the absolute value of the gain of the control loop comprising the magnetic sensor element (12), the feedback controller (50), and the magnetic field compensator (15) is larger than 10, preferably larger than 100.

8. The magnetic sensor device (10) according to claim 1,
characterized in that the feedback controller (50) comprises a nonlinearity-module that compensates non-linear behavior of the magnetic sensor element (12), the magnetic field generator (11, 13) and/or the magnetic field compensator (15).

9. The magnetic sensor device (10) according to claim 8,
characterized in that the nonlinearity-module comprises a geometry-dependant characteristic curve.

10. The magnetic sensor device (10) according to claim 1,
characterized in that the magnetic field generator (11, 13) and/or the magnetic field compensator (15) comprise conductor wires.

11. The magnetic sensor device (10) according to claim 1,
characterized in that the magnetic field compensator (15) is disposed in the vicinity of the magnetic sensor element (12).

12. The magnetic sensor device (10) according to claim 1,
characterized in that the magnetic field compensator (15) is at least partially realized by the same electronic components as the magnetic field generator (11, 13) and/or the magnetic sensor element (12).

13. The magnetic sensor device (10) according to claim 1,
characterized in that the magnetic sensor element comprises a magneto-resistive element like a GMR (12), a TMR, or an AMR element.

14. The magnetic sensor device (10) according to claim 1,
characterized in that the magnetic sensor device (10) is realized as an integrated circuit.

15. The magnetic sensor device (10) according to claim 14,
characterized in that signal processing circuits which are disposed in the vicinity of the magnetic sensor element (12) are comprised.

16. A method for detecting magnetized particles (2) in an investigation region, the method comprising the following steps:
a) generating an alternating magnetic excitation field (B1) in the investigation region;
b) generating a magnetic compensation field (B3) in a magnetic sensor element (12) such that predetermined spectral components of all magnetic fields (B2, B3, BXT, Bintf) which are effective in the magnetic sensor element (12) substantially cancel;
c) determining with the help of said magnetic sensor element (12) magnetic reaction fields (B2) generated by the magnetized particles (2) in reaction to the magnetic excitation field (B1).

17. The method according to claim 16,
characterized in that characteristics of the system behavior are determined by calibration measurements and taken into account during the generation of the magnetic compensation field (B3).

18. Use of the magnetic sensor device (10) according to claim 1 for molecular diagnostics, biological sample analysis, or chemical sample analysis.
